(19) United States
(12) Patent Application Publication
(10) Pub. No.: US 2022/0172926 A1
(43) Pub. Date: Jun. 2, 2022

(54) PLASMA PROCESSING APPARATUS AND METHOD FOR FABRICATING SEMICONDUCTOR DEVICE USING THE SAME

(71) Applicant: SAMSUNG ELECTRONICS CO., LTD., Suwon-si (KR)

(72) Inventors: Dong Wan Kim, Suwon-si (KR); Beom Rae Kim, Seoul (KR); Dong Hyeon Na, Hwaseong-si (KR); Young Jin Noh, Ansan-si Gyeonggi-do (KR); Seung Bo Shim, Seoul (KR); Sang-Ho Lee, Hwaseong-si (KR); Yong Woo Lee, Hwaseong-si (KR); Jun Ho Lee, Hwaseong-si (KR); Dong Hee Han, Seongnam-si (KR)

(21) Appl. No.: 17/443,535

(22) Filed: Jul. 27, 2021

(30) Foreign Application Priority Data
Dec. 1, 2020 (KR) 10-2020-0165336

(51) Int. Cl. H01J 37/32

(52) U.S. Cl. CPC H01J 37/32165; H01J 37/32137; H01J 37/32642; H01J 2237/334; H01J 37/321; H01J 2237/002; H01J 37/32541

(57) ABSTRACT

A method for fabricating a semiconductor device includes providing a wafer on a lower electrode inside a plasma processing apparatus. A first power having a first and second frequency is provided to the lower electrode. A second power is provided to an RF induction electrode through the lower electrode. A third power having the second frequency is released outside of a chamber. A plasma process is performed on the wafer while the third power is released. The RF induction electrode is disposed inside an insulating plate surrounding a sidewall of the lower electrode. The RF induction electrode is spaced apart front the lower electrode. The RF induction electrode has an annular shape surrounding the sidewall of the lower electrode. The first power is controlled by a first controller, and the third power is controlled by a second controller different from the first controller.

### CROSS-REFERENCE TO RELATED APPLICATION

This application claims priority under 35 U.S.C. § 119 to Korean Patent Application No. 10-2020-0165336, filed on Dec. 1, 2020 in the Korean Intellectual Property Office, the contents of which are incorporated by reference in its entirety.

### TECHNICAL FIELD

The present disclosure relates to a plasma processing apparatus and a method for fabricating a semiconductor device using the same.

### DISCUSSION OF THE RELATED ART

To provide memory devices that can store larger quantities of memory within a small form factor, many memory devices are constructed using a stacked structure in which multiple layers of memory cells are stacked within a single package. As the number of stacked layers found within next-generation V-NAND products increases, high aspect ratio etching is used.

Edge block impedance controller (EBIC) technology is used in next-generation V-NAND production to help control an etching rate in the edge region of a wafer. However, the EBIC technology can cause a reduction in the etching rate in the edge region of the wafer and this can lead to asymmetric, etching along the direction of the wafer.

### SUMMARY

A method for fabricating a semiconductor device includes providing a wafer on a lower electrode disposed inside a plasma processing apparatus, providing, a first power of a first frequency and a second frequency lower than the first frequency to the lower electrode, inducing a second power lower than the first power within an RF induction electrode using the lower electrode, releasing a third power lower than the second power and having the second frequency to an outside of a chamber, and performing a plasma process on the wafer while the third power is released to the outside of the chamber, wherein the RF induction electrode is disposed inside an insulating plate at least partially surrounding a sidewall of the lower electrode, wherein the RF induction electrode is spaced apart from the lower electrode, and the RF induction electrode has an annular shape at least partially surrounding the sidewall of the lower electrode, and wherein the first power is controlled by a first controller, and the third power is controlled by a second controller different from the first controller.

A plasma processing apparatus includes a chamber in which a plasma process is performed, a lower electrode disposed inside the chamber and configured to receive a first power of a first frequency and a second frequency lower than the first frequency, an insulating plate at least partially surrounding a sidewall of the lower electrode, a focus ring disposed on an edge of the lower electrode and on the insulating plate, an RF induction electrode spaced apart from the lower electrode in the insulating plate and having an annular shape at least partially surrounding the sidewall of the lower electrode, a second power lower than the first power being induced within the RF induction electrode using the lower electrode, an RF output rod connected to the RF induction electrode and configured to release a third power lower than the second power to an outside of the chamber, the third power having the second frequency; and an RF induction rod connecting the RF induction electrode to the RF output rod and penetrating the insulating plate.

A plasma processing apparatus includes a chamber in which a plasma process is performed, a lower electrode disposed inside the chamber and configured to receive a first power of a first frequency and a second frequency lower than the first frequency, an RF induction electrode spaced apart from the lower electrode and having an annular shape at least partially surrounding a sidewall of the lower electrode, a second power lower than the first power being induced within the RF induction electrode by the lower electrode, an RF output rod including a plurality of RF connection lines spaced apart from each other at a same angle and an RF output line connected to each of the plurality of RF connection lines, and configured to release a third power lower than the second power to an outside of the chamber, the third power having the second frequency, a first controller configured to control the first power, and a second controller, different from the first controller, configured to control the third power.

### BRIEF DESCRIPTION OF THE DRAWINGS

The above and other aspects and features of the present disclosure will become more apparent by describing in detail exemplars/embodiments thereof with reference to the attached drawings, in which:

FIG. 1 illustrates a plasma processing apparatus according to embodiments of the present disclosure;

FIG. 2 is an enlarged view of area R of FIG. 1;

FIG. 3 is a plan view illustrating an internal structure of a plasma processing apparatus according to embodiments of the present disclosure;

FIG. 4 is a perspective view illustrating an internal structure of a plasma processing apparatus according to embodiments of the present disclosure;

FIG. 5 is a diagram illustrating an RF filter of a plasma processing apparatus according to embodiments of the present disclosure;

FIG. 6 is a flowchart illustrating a method for fabricating a semiconductor device using a plasma processing apparatus according to embodiments of the present disclosure;

FIG. 7 is a graph illustrating each of the RF power provided to the lower electrode and the RF power released to the outside of the chamber in a method for fabricating a semiconductor device according to embodiments of the present disclosure;

FIG. 8 is a graph illustrating each of the RF power provided to the lower electrode and the RF power released to the outside of the chamber in a method for fabricating a semiconductor device according to embodiments of the present disclosure;

FIG. 9 is a graph illustrating each of the RF power provided to the lower electrode and the RF power released to the outside of the chamber in a method for fabricating a semiconductor device according to embodiments of the present disclosure;

FIG. 10 is a graph illustrating each of the RF power provided to the lower electrode and the RF power released to the outside of the chamber in a method for fabricating a semiconductor device according to embodiments of the present disclosure;

FIG. 11 illustrates a plasma processing apparatus according to embodiments of the present disclosure;

FIG. 12 illustrates a plasma processing apparatus according to embodiments of the present disclosure;

FIG. 13 is a perspective view illustrating an internal structure of a plasma processing apparatus according to embodiments of the present disclosure;

FIG. 14 illustrates a plasma processing apparatus according to embodiments of the present disclosure;

FIG. 15 is a plan view illustrating an internal structure of a plasma processing apparatus according to embodiments of the present disclosure;

FIG. 16 illustrates a plasma processing apparatus according to embodiments of the present disclosure;

FIG. 17 is a plan view illustrating an internal structure of a plasma processing apparatus according to embodiments of the present disclosure;

FIGS. 18 and 19 are perspective views illustrating an internal structure of a plasma processing apparatus according to embodiments of the present disclosure; and

FIG. 20 is a plan view illustrating an internal structure of a plasma processing apparatus according to embodiments of the present disclosure.

### DETAILED DESCRIPTION OF THE EMBODIMENTS

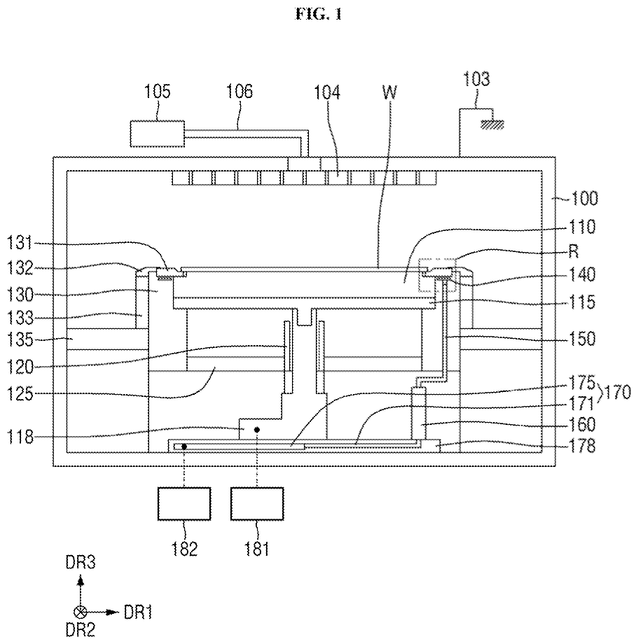

Hereinafter, a plasma processing apparatus according to embodiments of the present disclosure will be described with reference to FIGS. 1 to 5.

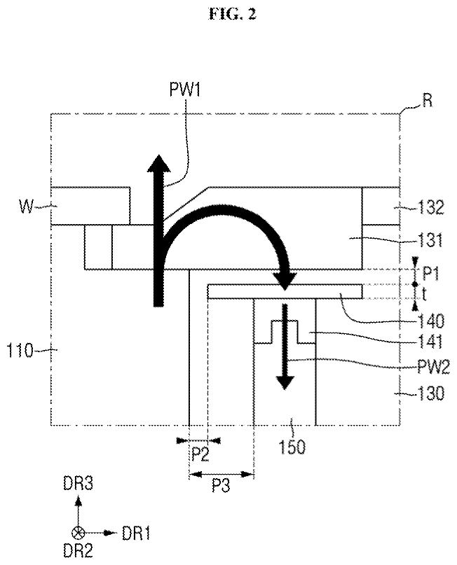

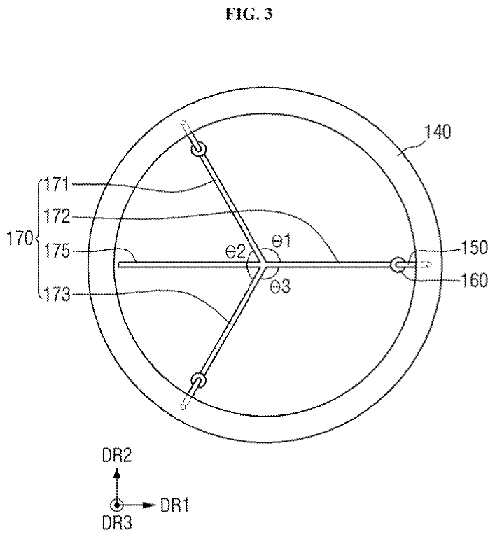

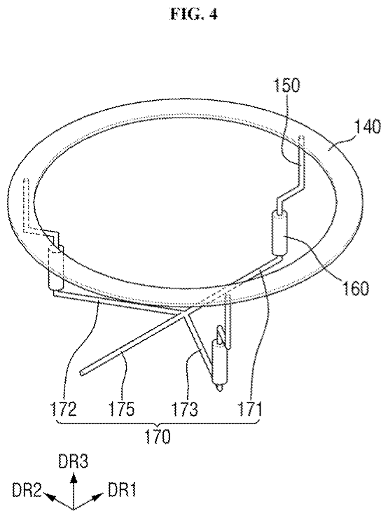

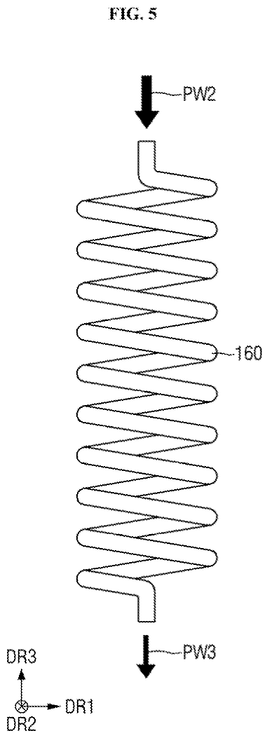

FIG. 1 illustrates a plasma processing apparatus according to embodiments of the present disclosure. FIG. 2 is an enlarged view of area R of FIG. 1. FIG. 3 is a plan view illustrating an internal structure of a plasma processing apparatus according to embodiments of the present disclosure. FIG. 4 is a perspective view illustrating an internal structure of a plasma processing apparatus according to embodiments of the present disclosure. FIG. 5 is a diagram illustrating an RF filter of a plasma processing apparatus according to embodiments of the present disclosure.

Referring to FIGS. 1 to 5, the plasma processing apparatus according to embodiments of the present disclosure includes a chamber 100, a ground line 103, a vas feeder 104, a gas source 105, and a gas supply line 106, a lower electrode 110, an RF plate 115, an RF rod 118, a ground electrode 120, a ground plate 125, an insulating plate 130, a focus ring 131, an edge ring 132, an insulator ring 133, a baffle unit 135, an RF induction electrode 140, an RF induction rod 150, an RF filter 160, an RF output rod 170, an RF output plate 178, a first controller 181, and a second controller 182.

The chamber 100 may serve as a housing that accommodates other components therein. The chamber 100 may he an isolated space where a plasma process is performed on a wafer W. Since the chamber 100 is isolated from the outside, the processing conditions of the plasma process may be adjusted. For example, the processing conditions such as a temperature or a pressure in the chamber 100 may be adjusted to he different from those in the outside.

The gas feeder 104 may be disposed at the ceiling (e.g., top-most surface) of the chamber 100. The gas feeder 104. may be disposed on the lower electrode 110. The gas feeder 104 may be grounded through the ground line 103. The gas feeder 104 may provide a gas toward the top surface of the wafer W placed on the lower electrode 110.

The gas feeder 104 may use a plurality of nozzles to provide a plasma generating gas into the chamber 100. In some embodiments, the gas feeder 104 may include an upper electrode for the plasma process. In some embodiments, the gas feeder 104 may directly serve as the upper electrode.

The plasma processing may include dry etching the top surface of the wafer W using plasma of the plasma generating gas. For example, the gas feeder 104 may provide the gas used for the plasma process into the chamber 100.

The gas supply line 106 may be connected to the gas feeder 104. The gas supply line 106 may he connected to the ceiling of the chamber 100. The gas supply line 106 may be connected to a gas source 105 that is located outside of the chamber 100. The gas supply line 106 may provide the plasma generating gas from the gas source 105 into the chamber 100. Although it is illustrated in FIG. 1 that the gas supply line 106 is disposed at the ceiling of the chamber 100, the location of the gas supply line 106 is not necessarily limited thereto. The location of the gas supply line 106 may be changed depending on the structure of the chamber 100 and the location of the gas source 105.

The gas source 105 may store the plasma generating gas and provide it into the chamber 100 during the plasma. process. Although it is illustrated in FIG. 1 that the gas source 105 provides the gas through the gas supply line 106 from the outside of the chamber 100, the present disclosure is not necessarily limited thereto. For example, the gas source 105 may be directly connected to the chamber 100.

The lower electrode 110 may be disposed in the chamber 100. The wafer W may be provided on the top surface of the lower electrode 110. The lower electrode 110 may operate as an electrostatic chuck to hold the wafer W using the voltage applied to the lower electrode 110.

The RF plate 115 may be disposed on the bottom surface of the lower electrode 110. For example, the central portion of the RF plate 115 may protrude toward the bottom surface of the chamber 100. Although it is illustrated in FIG. 1 that the width of the RF plate 115 in a first horizontal direction DR1 is equal to the width of the lower electrode 110 in the first horizontal direction DR1, present disclosure is not necessarily limited thereto. For example, the width of the RF plate 115 in the first horizontal direction DR1 may be different from the width of the lower electrode 110 in the first horizontal direction DR1.

The RF plate 115 may include a conductive material, for example, aluminum (Al), but the present disclosure is not necessarily limited thereto.

The RF rod 118 may be disposed below the RF plate 115. For example, the RF rod 118 may be connected to the protruding portion of the RF plate 115. The RF rod 118 may provide a first power PW1 to the lower electrode 110 through the RF plate 115. The first power PW1 may be, e.g., a radio frequency (RF) power having a component of a first frequency and a component of a second frequency lower than the first frequency.

The ground electrode 120 may at least partially surround the sidewall of the RF rod 118. The ground electrode 120 may be spaced apart from the sidewall of the RF rod 118. Further, the ground electrode 120 may be spaced apart from the RF plate 115.

The ground plate 125 may be disposed below the RF plate 115. The ground plate 125 may at least partially surround the sidewall of the ground electrode 120. The ground plate 125 may be in contact with the ground electrode 120. The ground plate 125 may be in contact with the outer wall of the chamber 100. The ground electrode 120 may be grounded to the outer wall of the chamber 100 through the ground plate 125.

The insulating plate 130 may at least partially surround each of the sidewall of the lower electrode 110 and the sidewall of the RF plate 115. The insulating plate 130 may be in contact with the ground plate 125. At least a part of the insulating plate 130 may be in contact with the bottom surface of the RF plate 115, but the present disclosure is not necessarily limited thereto. The insulating plate 130 may include an insulating material, e.g., ceramic.

The focus ring 131 may be disposed on the edge of the top surface of the lower electrode 110 and on at least a part of the top surface of the insulating plate 130. The focus ring 131 may at least partially surround a part of the upper sidewall of the lower electrode 110. The focus ring 131 may have an annular shape. The focus ring 131 may include an insulating material.

The insulator ring 133 may at least partially surround the sidewall of the insulating plate 130. The insulator ring 133 may be in contact with the sidewall of the insulating plate 130. The insulator ring 133 may be spaced apart from the focus ring 131. The insulator ring 133 may have an annular shape. The insulator ring 133 may include an insulating material.

The edge ring 132 may be disposed on a part of the top surface of the insulating plate 130 and on the top surface of the insulator ring 133. The edge ring 132 may at least partially surround the sidewall of the focus ring 131. The edge ring 132 may be in contact with each of the insulating plate 130, the insulator ring 133, and the focus ring 131. The edge ring 132 may have an annular shape. The edge ring 132 may include an insulating material.

The baffle unit 135 may be disposed between the insulating plate 130 and the sidewall of the chamber 100. However, present disclosure is not necessarily limited thereto. In some embodiments, the baffle unit 135 may be disposed between the insulator ring 133 and the sidewall of the chamber 100.

The baffle unit 135 may he in contact with each of the sidewall of the chamber 100 and the sidewall of the insulating plate 130. However, present disclosure is not necessarily limited thereto. In some embodiments, the baffle unit 135 may be spaced apart from any one of the sidewall of the chamber 100 and the sidewall of the insulating plate 130.

The baffle unit. 135 may have an annular shape. The baffle unit 135 may have a plurality of baffle holes penetrating the baffle unit 135 in a vertical direction DR3. The plurality of baffle holes may be spaced apart from each other. The processing gas in the chamber 100 may be exhausted through the baffle holes formed in the baffle unit 135.

The RF induction electrode 140 may be disposed in the insulating plate 130. For example, the RF induction electrode 140 may he embedded in the insulating plate 130. The RF induction electrode 140 may be disposed adjacent to the focus ring 131 disposed on the top surface of the insulating plate 130.

The RF induction electrode 140 may be spaced apart from the focus ring 131 by a first distance P1 in the vertical direction DR3. A first gap P1 may be, e.g., within a range of 1 mm to 5 mm. By setting the first gap P1 to be within a range of 1 mm to 5 mm, the coupling between the RF induction electrode 140 and the focus ring 131 may be enhanced. For example, the RF power provided by the lower electrode 110 may be effectively induced to the RF induction electrode 140. Accordingly, the etching rate at the edge of the wafer W is increased, which makes it possible to reduce an extent of the etching variation for the wafer W. When the first gap P1 is greater than 5 mm, the RF power induced from the lower electrode 110 to the RF induction electrode 140 is reduced and, thus, the etching variation may be reduced.

A thickness t of the RF induction electrode 140 in the vertical direction DR3 may be within a range of 5 μm to 100 μm. By setting the thickness t of the RF induction electrode 140 to be within a range of 5 μm to 100 μm, the volume of the RF induction electrode 140 in the insulating. plate 130 may be reduced. Accordingly, it is possible to prevent the structures of the insulating plate 130, the focus ring 131, the lower electrode 110, and the like from being deformed by the thermal expansion of the RF induction electrode 140. When the thickness t of the RF induction electrode 140 is greater than 100 μm, the thermal expansion of the RF induction electrode 140 causes structural detects of the plasma processing apparatus, which may result in deterioration of the efficiency of the plasma process.

The RF induction electrode 140 may at least partially surround the sidewall of the lower electrode 110. The RF induction electrode 140 may be spaced apart from the sidewall of the lower electrode 110 by a second gap P2. The RF induction electrode 140 may have an annular shape. The RF induction electrode 140 may include a conductive material.

As illustrated in FIG. 2, a part of the first power PW1 provided by the lower electrode 110 may be provided to the space between the wafer W and the gas feeder 104 through the focus ring 131. Further, the other part of the first power PW1 provided by the lower electrode 110 may be induced to the RF induction electrode 140 through the focus ring 131. The RF power induced to the RF induction electrode 140 may be a second power PW2 lower than the first power PW1. The second power PW2 may have, e.g., a component with a first frequency and a component with a second frequency lower than the first frequency.

A part of the RF induction rod 150 may penetrate the insulating plate 130. The other part of the RF induction rod 150 may extend to the position below the insulating plate 130. The RF induction rod 150 may be connected to the RF induction electrode 140 through an RF induction electrode connection portion 141.

There may be a plurality of RF induction rods 150. For example, as illustrated in FIGS. 3 and 4. three RF induction rods 150 may be connected to the RF induction electrode 140. The RF induction rod 150 may have, e.g., a line segment shape. However, present disclosure is not necessarily limited thereto.

The width of the RF induction rod 150 in the first horizontal direction DR1 may be smaller than the width of the RF induction electrode 140 in the first horizontal direction DR1. The RF induction rod 150 may be spaced apart from the sidewall of the lower electrode 110 by a third gap P3. The second gap P2 between the RF induction electrode 140 and the sidewall of the lower electrode 110 may be smaller than the third gap P3 between the RF induction rod. 150 and the sidewall of the lower electrode 110. Accordingly, it is possible to reduce the RF power directly induced from the sidewall of the lower electrode 110 to the RF induction rod 150. The RF induction rod 150 may include a conductive material.

The RF filter 160 may be connected to one end of the RF induction rod 150 in the chamber 100. For example, the RF induction rod 150 may connect the RF induction electrode 140 and the RF filter 160. The number of the RF filters 160 may correspond to those of the RF induction rods 150. The RF filter 160 may have, e.g., a coil shape.

The RF filter 160 may provide a third power PW3 generated by removing the RF power having a relatively high first frequency from the second power PW2 provided from the RF induction electrode 140 through the RF induction rod 150 to the RF output rod 170. for example. the RF filter 160 may allow the RF power having the second frequency to be provided to the RF output rod 170 and block the RF power having the first frequency higher than the second frequency. Accordingly, the third power PW3 provided to the RF output rod 170 may have the RF power having a relatively low second frequency.

The RF power having the first frequency may be used for the plasma process. It is possible to increase the efficiency of the plasma process by preventing the RF power having the first frequency used for the plasma process from being released to the outside of the chamber 100 using the RF filter 160.

The RF output rod 170 may be connected to the RF filter 160. For example, the RF filter 160 may connect the RF induction rod 150 and the RF output rod 170. The RF output rod 170 may be connected to the RF induction electrode 140 through the RF filter 160 and the RF induction rod 150.

The RF output, rod 170 may be disposed in the RF output plate 178 disposed on the bottom surface of the chamber 100. However, present disclosure is not necessarily limited thereto. The RF output plate 178 may include an insulating material.

The RF output rod 170 may include a plurality of RF connection lines and an RF output line 175. The number of the RF connection lines may correspond to the number of the RF induction rods 150. The RF output rod 170 may include, e.g., first to third RF connection lines 171, 172, and 173.

Each of the first to third RF connection lines 171, 172, and 173 may have a line segment shape. One ends of the first to third RF connection lines 171, 172, and 173 may be connected to each other. The other ends of the first to third RF connection lines 171 172, and 173 may be connected to the RF filter 160.

The first to third RF connection lines 171, 172, and 173 may be spaced apart from each other, may occupy a single plane, and may form angles with respect to one another that are the same. The single plane may be the plane defined by the first horizontal direction DR1 and a second horizontal direction DR2 perpendicular to the first horizontal direction DR1. For example, as illustrated in FIG. 3, the first RF connection line 171 may be spaced apart from the second RF connection line 172 and the two lines may form a first angle θ1. The second RF connection line 172 may be spaced apart from the third RF connection line 173 and the two lines may form a second angle θ2. The third RF connection line 173 may be spaced apart from the first RF connection line 171 and the two lines may form a third angle θ3. The first to third angles θ1, θ2, and θ3 may be equal to one another.

Since the first to third RF connection lines 171, 172, and 173 are spaced apart from each other and form the same angle, the RF induction rod 150 may be disposed in the optimal path for transmitting the RF power. Accordingly, an extent of the etching variation for the wafer W may be decreased.

The RF output line 175 may be connected to the portion where the first to third RF connection lines 171, 172, and 173 are connected to each other. The RF output line 175 may have a line segment shape. For example, the RF output line 175 may be disposed on the same plane as the plane on which the first to third RF connection lines 171, 172, and 173 are arranged. However, present disclosure is not necessarily limited thereto. For example, the RF output line 175 may be disposed between the second RF connection line 172 and the third RF connection lines 173.

Each of the first to third RF connection lines 171, 172, and 173, and the RF output line 175 may include a conductive material. The third power PW3 provided through the RF filter 160 may be released to the outside of the chamber 100 through the first to third RF connection lines 171, 172, and 173, and the RF output line 175.

The first controller 181 may be connected to the RF rod 118. The first controller 181 may provide the first power PW1 to the RF rod 118. The first controller 181 may control the first power PW1 provided to the RF rod 118.

The second controller 182 may be connected to the RF output rod 170. For example, the second controller 182 may be connected to the RF output line 175 of the RF output rod 170. The second controller 182 may be different from the first controller 181. For example, each of the second controller 182 and the first controller 181 may be driven independently from one another.

The second controller 182 may control the third power PW3 released to the outside of the chamber 100 through the RF output rod 170.

Hereinafter, a method for fabricating a semiconductor device using a plasma processing apparatus according to embodiments of the present disclosure will be described with reference to FIGS. 1 to 7.

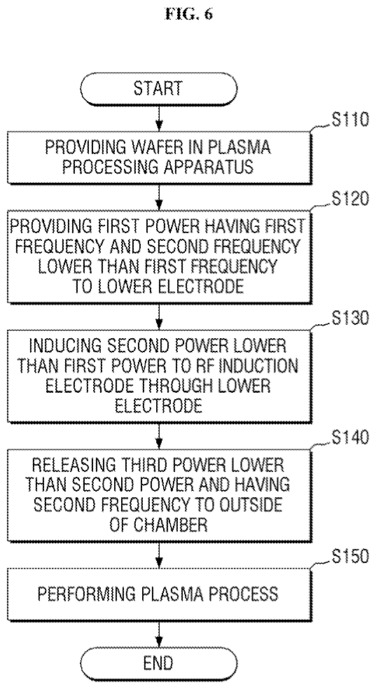

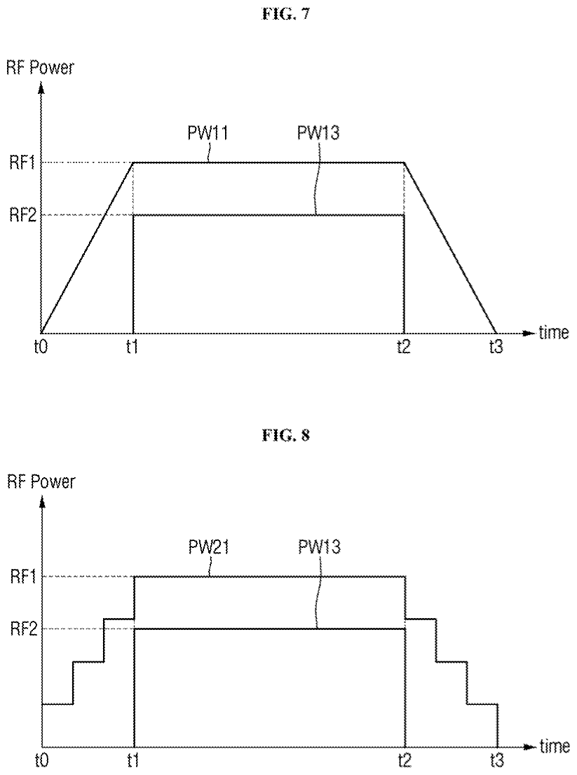

FIG. 6 is a flowchart illustrating a method for fabricating a semiconductor device using a plasma processing apparatus according to embodiments of the present disclosure. FIG. 7 is a graph illustrating each of the RF power provided to the lower electrode and the RF power released to the outside of the chamber in a method for fabricating a semiconductor device according to embodiments of the present disclosure.

In FIG. 7, the horizontal axis represents time and the vertical axis represents an RF power. For example, in FIG. 7, a first time to may indicate a time at which the supply of a first power PW11 to the lower electrode 110 is started, a second time t1 may indicates a time at which the plasma process is started in the chamber 100, a third time t2 may indicate a time at which the plasma process is ended in the chamber 100, and a fourth time t3 may indicate a time at which the supply of the first power PW11 to the lower electrode 110 is completely blocked.

Referring to FIGS. 1 to 7, the wafer W may be provided in the plasma processing apparatus (step S110). The wafer W may be provided on the top surface of the lower electrode 110 disposed in the plasma processing apparatus.

Then, the first power PW11 having a first frequency and a second frequency lower than the first frequency may be provided to the lower electrode 110 (step S120). The first power PW11 may be provided to the lower electrode 110 through the RF rod 118 and the RF plate 115.

The first controller 181 may control the first power PW11 provided to the lower electrode 110. The first controller 181 may increase the first power PW11 provided to the lower electrode 110 from the first time t0 to the second time t1 up to the first RF power RF1 with a constant inclination (e.g., a linear slope) in the graph of FIG. 7.

Then, the second power PW2 (see FIG. 2) having an RF power lower than the first RF power RF1 of the first power PW11 may he induced to the RF induction electrode 140 through the lower electrode 110 (step S130). The second power PW2 (see FIG. 2) may have both a component with a first frequency and a component with a second frequency lower than the first frequency.

Then, the second power PW2 (see FIG. 2) induced to the RF induction electrode 140 may be provided to the RF filter 160 through the RF induction rod 150. A third power PW13 having a second frequency and having a second RF power RF2 lower than the RF power of the second power PW2 (see FIG. 2) may be generated using the RF filter 160.

The third power PW13 generated using the RF filter 160 may be released to the outside of the chamber 100 through the RF output rod 170 (step S140). The second controller 182 may control the third power PW13 released to the outside of the chamber 100. Then, the plasma process may be performed on the wafer W while the third power PW 13 is being released to the outside of the chamber (step S150). The plasma process may be performed from the second time t1 to the third time t2.

During the plasma process, for example, the first controller 181 may control the first power PW11 provided to the lower electrode 110 to be maintained at the first RF power RF1, which may be a constant power level. Further, for example, the second controller 182 may control the third power PW13 released to the outside of the chamber 100 to be maintained at the second RF power RF2, which may be a constant power level. However, present disclosure is not necessarily limited thereto.

After the plasma process is ended, the first controller 81 may decrease the first power PW11 provided to the lower electrode 110 from the third time t2 to the fourth time t3 with a constant inclination in the graph of FIG. 7. For example, the first power PW11 may be decreased to 0 Watts. After the plasma process is ended, the second controller 162 may prevent the third power PW13 from being released to the outside of the chamber 100.

Hereinafter, a method for fabricating a semiconductor device according to embodiments of the present disclosure will be described with reference to FIG. 8. The description will focus on differences from the method of fabricating the semiconductor device illustrated in FIGS. 6 and 7.

FIG. 8 is a graph illustrating each of the RF power provided to the lower electrode and the RF power released to the outside of the chamber in a method for fabricating a semiconductor device according to embodiments of the present disclosure.

Referring to FIG. 8, in the method for fabricating a semiconductor device according to embodiments of the present disclosure, after the wafer W is provided in the plasma processing apparatus, the first controller 181 (see FIG. 1) may increase the first power PW21 provided to the lower electrode 110 (see FIG. 1) up to the first RF power RF1 from the first time t0 to the second time t1 in a stepped manner shown in the graph of FIG. 8.

After the plasma process is ended, the first controller 181 (see FIG. 1) may decrease the first power PW21 provided to the lower electrode 110 (see FIG. 1) from the third time t2 to the fourth time t3 in a stepped manner shown in the graph of FIG. 8.

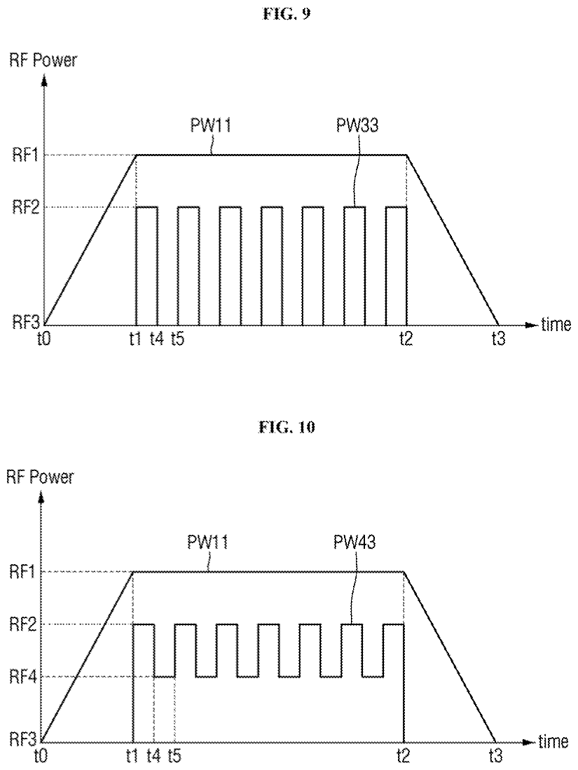

Hereinafter, a method for fabricating a semiconductor device according to embodiments of the present disclosure will be described with reference to FIG. 9. The description will focus on differences from the method of fabricating the semiconductor device illustrated in FIGS. 6 and 7 and to the extent that details concerning some elements are omitted, it may be assumed that the elements with omitted details are at least similar to corresponding elements described elsewhere in the instant disclosure.

FIG. 9 is a graph illustrating each of the RF power provided to the lower electrode and the RF power released to the outside of the chamber in a method for fabricating a semiconductor device according to embodiments of the present disclosure.

Referring to FIG. 9, in the method for fabricating a semiconductor device according to embodiments of the present disclosure, the second controller 182 (see FIG. 1) may repetitively control a third power PW33 released to the outside of the chamber 100 (see FIG. 1) between the second RF power RH and the third RF power RF3 lower than the second RF power RF2 at regular intervals while the plasma process is performed.

For example, while the plasma process is performed, the second controller 182 (see FIG. 1) may control the third power PW33 released to the outside of the chamber 100 (see FIG. 1) to the second RF power RF2 from the second time t1 to a fifth time t4. Further, the second controller 182 (see FIG. 1) may control the third power PW33 released to the outside of the chamber 100 (see FIG. 1) to the third RF power RF3 lower than the 2 RF power RF2 from the fifth time t4 to a sixth time t5. In this case, the third RF power RF3 may be, e.g., 0 Watts.

The second controller 182 (see FIG. 1) may control the third power PW33 released to the outside of the chamber 100 (see FIG. 1) while repeating, the cycle from the second time t1 to the sixth time t5 between the second time t1 and the third time t2 during which the plasma process is performed.

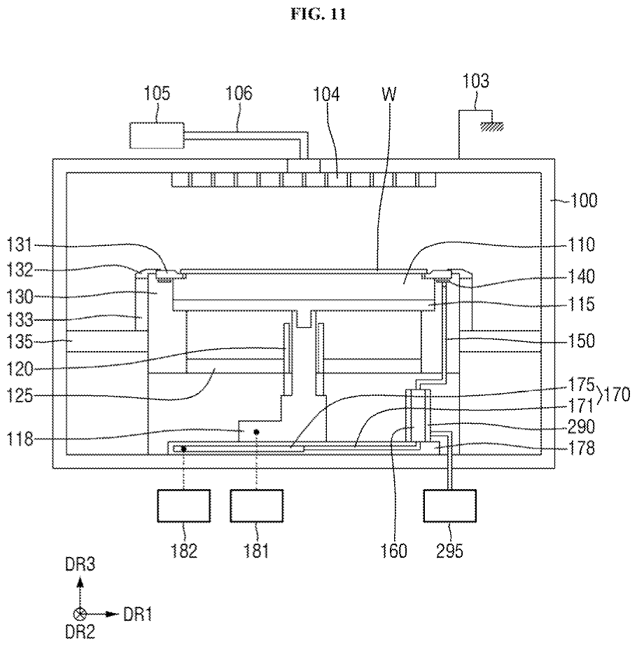

Hereinafter, a method for fabricating a semiconductor device according to embodiments of the present disclosure will be described with reference to FIG. 10. The description will focus on differences from the method of fabricating the semiconductor device illustrated in FIGS. 6 and 7 and to the extent that details concerning some elements are omitted, it may be assumed that the elements with omitted details are at least similar to corresponding elements described elsewhere in the instant disclosure.

FIG. 10 is a graph illustrating each of the RF power provided to the lower electrode and the RF power released to the outside of the chamber in a method for fabricating a semiconductor device according to embodiments of the present disclosure.

Referring to FIG. 10, in the method for fabricating a semiconductor device according to embodiments of the present disclosure, the second controller 182 (see FIG. 1) may repetitively control a third power PW43 released to the outside of the chamber 100 (see FIG. 1) between the second RF power RF2 and the fourth RF power RF4 lower than the second RF power RF2 regular intervals while the plasma process is performed.

For example, while the plasma process is performed, the second controller 182 (see FIG. 1) may control the third power PW43 released to the outside of the chamber 100 (see FIG. 1) to the second RF power RF2 from the second time to the fifth time t4. Further, the second controller 182 (see FIG. 1) may control the third power PW43 released to the outside of the chamber 100 (see FIG. 1) to the fourth RF power RF4 lower than the second RF power RF2 from the fifth time t4 to the sixth time t5. In this case, the fourth RF power RF4 may be greater than 0 Watts.

The second controller 182 (see FIG. 1) may control the third power PW43 released to the outside of the chamber 100 (see FIG. 1) while repeating the cycle from the second time t1 to the sixth time t5 between the second time t1 and the third time t2 during which the plasma process is performed.

Hereinafter, a plasma processing apparatus according to embodiments of the present disclosure will be described with reference to FIG. 11. The description will focus on differences from the plasma processing apparatus illustrated in FIGS. 1 to 5 and to the extent that details concerning some elements are omitted, it may be assumed that the elements with omitted details are at least similar to corresponding elements described elsewhere in the instant disclosure.

FIG. 11 illustrates a plasma processing apparatus according to embodiments of the present disclosure.

Referring to FIG. 11, the plasma processing apparatus according, to embodiments of the present disclosure may include a cooling unit 290 for cooling the RF filter 160.

The cooling unit 290 may be disposed in the chamber 100. The cooling unit 290 may be connected to the RF filter 160. For example, the cooling unit 290 may at least partially surround the RF filter 160. The cooling unit 290 may cool the RF filter 160 using a coolant or air.

A cooling controller 295 may be disposed outside the chamber 100, for example. However, present disclosure is not necessarily limited thereto. The cooling controller 295 may provide a coolant or air to the cooling unit 290. The cooling controller 295 may control the coolant or the air provided to the cooling unit 290 to adjust the temperature of the RF filter 160.

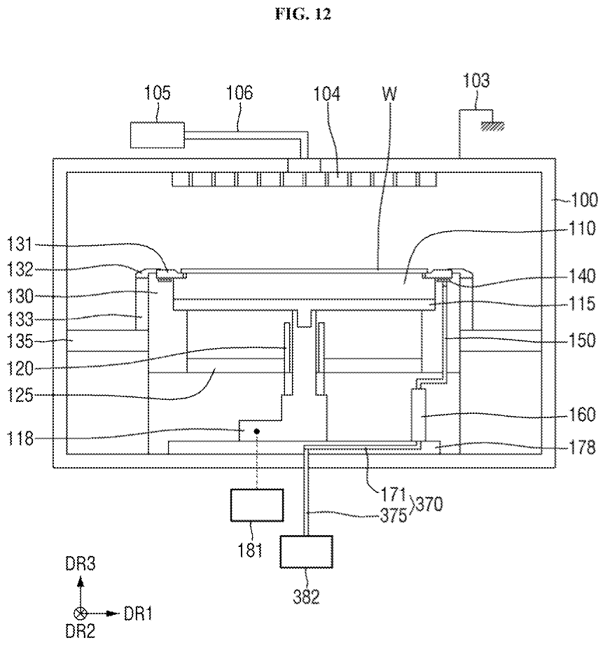

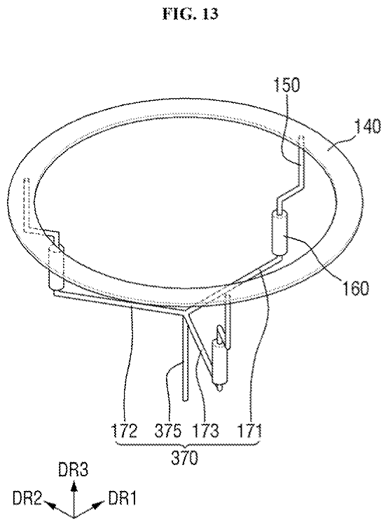

Hereinafter, a plasma processing apparatus according to embodiments of the present disclosure will be described with reference to FIGS. 12 and 13. The description will focus on differences from the plasma processing apparatus illustrated in FIGS. 1 to 5 and to the extent that details concerning; some elements are omitted, it may be assumed that the elements with omitted details are at least similar to corresponding elements described elsewhere in the instant disclosure.

FIG. 12 illustrates a plasma processing apparatus according to embodiments of the present disclosure. FIG. 13 is a perspective view illustrating an internal structure of a plasma processing apparatus according to embodiments of the present disclosure.

Referring to FIGS. 12 and 13, in the plasma processing apparatus according to embodiments of the present disclosure, an RF output line 375 of an RF output rod 370 may extend to the outside of the chamber 100.

The RF output line 375 may extend in the vertical direction DR3 perpendicular to the plane on which the first to third RF connection lines 171, 172, and 173 are arranged. Since the RF output line 375 is disposed in the vertical direction DR3, it is possible to minimize the interference between the RF output line 375 and each of the first to third RF connection lines 171, 172, and 173. A second controller 382 may be directly connected to, e.g., the RF output line 375.

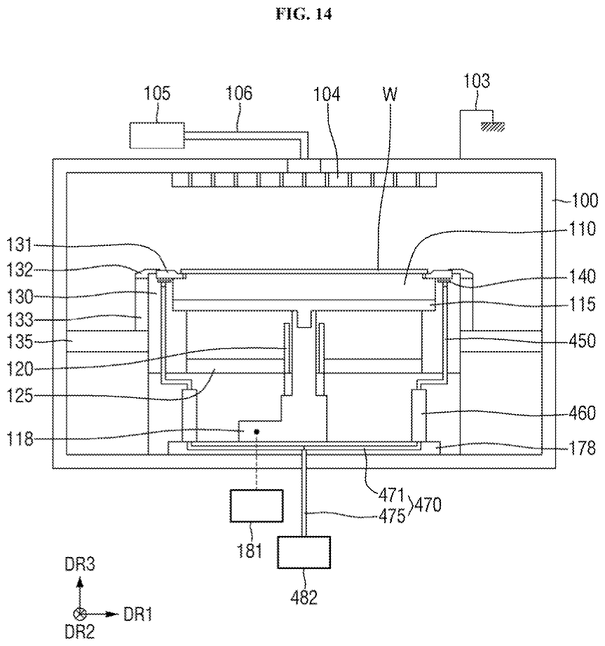

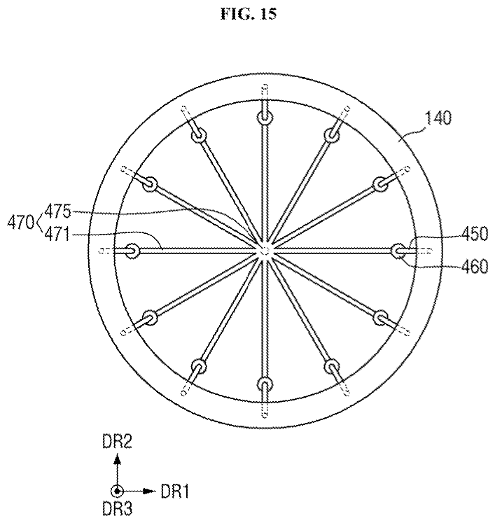

Hereinafter, a plasma processing apparatus according to embodiments of the present disclosure will be described with reference to FIGS. 14 and 15. The description will focus on differences from the plasma processing apparatus illustrated in FIGS. 1 to 5 and to the extent that details concerning some elements are omitted, it may be assumed that the elements with omitted details are at least similar to corresponding elements described elsewhere in the instant disclosure.

FIG. 14 illustrates a plasma processing apparatus according to embodiments of the present disclosure. FIG. 15 is a plan view illustrating an internal structure of a plasma processing apparatus according to embodiments of the present disclosure.

Referring to FIGS. 14 and 15, in the plasma processing apparatus according to embodiments of the present disclosure, an RF output rod 470 may include an RF output line 475 and four or more RF connection lines 471.

The plurality of RF connection lines 471 may be arranged radially. One ends of the plurality of RF connection lines 471 may be connected to each other. The plurality of RF connection lines 471 may be spaced apart from each other and may form a same angle with each other. The plurality of RF connection lines 471 may all be disposed on the plane defined by the first horizontal direction DR1 and the second horizontal direction DR2.

The RF output line 475 may extend in the vertical direction DR3 perpendicular to the plane on which the plurality of RF connection lines 471 are arranged. Since the RF output line 475 is disposed in the vertical direction DR3, it is possible to minimize the interference between the RF output line 475 and each of the plurality of RF connection lines 471. The second controller 482 may be directly connected to, e.g., the RF output line 475.

The number of the RF filters 460 and the number of the RF induction rods 450 may correspond to those of the plurality of RF connection lines 471. Each of the plurality of RF connection lines 471 may be connected to each of the RF filters 460.

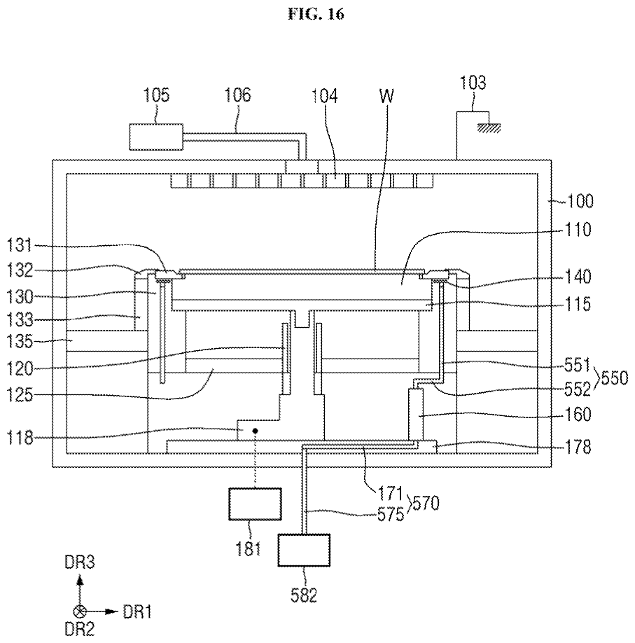

Hereinafter, a plasma processing apparatus according to embodiments of the present disclosure will be described with reference to FIGS. 16 to 19. The description will focus on differences from the plasma processing apparatus illustrated in FIGS. 1 to 5 and to the extent that details concerning some elements are omitted, it may be assumed that the elements with omitted details are at least similar to corresponding elements described elsewhere in the instant disclosure.

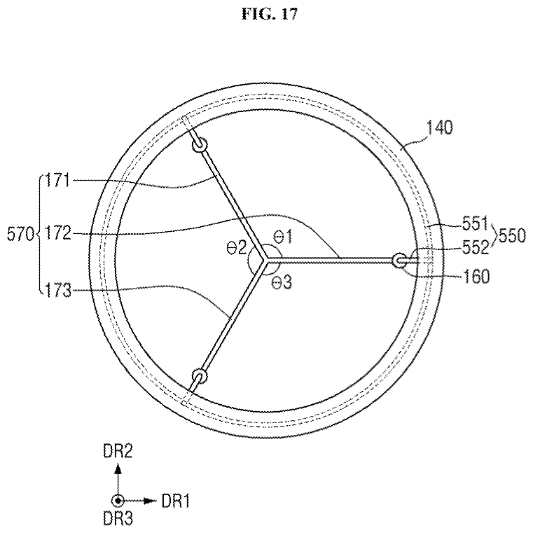

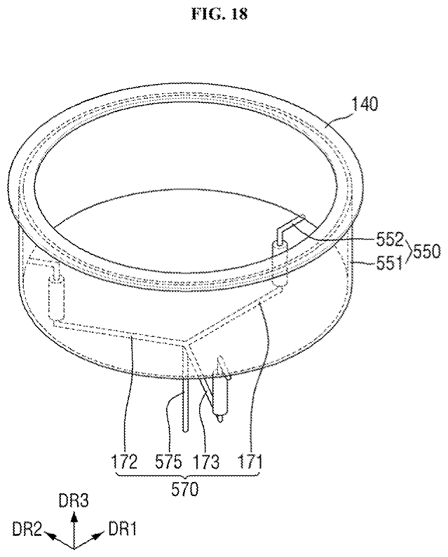

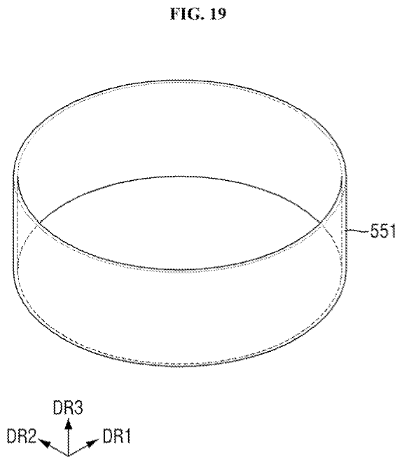

FIG. 16 illustrates a plasma processing apparatus according to embodiments of the present disclosure. FIG. 17 is a plan view illustrating an internal structure of a plasma processing apparatus according to embodiments of the present disclosure. FIGS. 18 and 19 are perspective views illustrating an internal structure of a plasma processing apparatus according to embodiments of the present disclosure.

Referring to FIGS. 16 to 19, in the plasm, processing apparatus according to embodiments of the present disclosure, an RF induction rod 550 may have a partially hollow cylindrical shape (e.g., a pipe shape). The RF induction rod 550 may have a first portion 551 having a cylindrical shape and a second portion 552 having a line segment shape.

The first portion 551 of the RF induction rod 550 may be connected to the RF induction electrode 140. The thickness of the first portion 551 of the RF induction rod 550 in the first horizontal direction DR1 may be smaller than the width of the RF induction electrode 140 in the first horizontal direction DR1.

The first portion 551 of the RF induction rod 550 may penetrate the insulating plate 130 in the vertical direction DR3. For example, at least a part of the first portion 551 of the RF induction rod 550 may protrude to the position below the insulating plate 130. However, present disclosure is not necessarily limited thereto.

The second portion 552 of the RF induction rod 550 may connect the first portion 551 of the RF induction rod 550 and the RF filter 160. For example, the first portion 551 of the RF induction rod 550 may be connected to the RF output rod 570 through the second portion 552 of the RF induction rod 550 and the RF filter 160.

The RF output line 575 of the RF output rod 570 may extend to the outside of the chamber 100. The RF output line 575 may extend in the vertical direction DR3 perpendicular to the plane on which the first to third RF connection lines 171, 172, and 173 are arranged. Since the RF output line 575 is disposed in the vertical direction DR3, it is possible to minimize the interference between the RF output line 575 and each of the first to third RF connection lines 171, 172, and 173. However, present disclosure is not necessarily limited thereto. In embodiments, the RF output line 575 may be disposed on the same plane as the plane on which the first to third RF connection lines 171, 172, and 173 are arranged. The second controller 582 may be directly connected to, e.g., the RF output line 575.

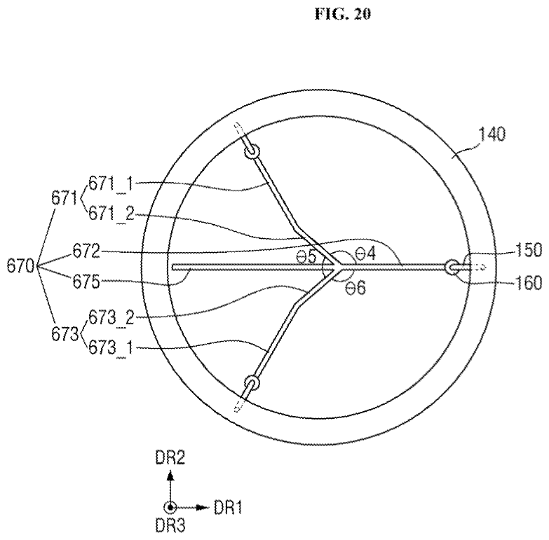

Hereinafter, a plasma processing apparatus according to embodiments of the present disclosure will he described with reference to FIG. 20. The description will focus on differences from the plasma processing apparatus illustrated in FIGS. 1 to 5 and to the extent that details concerning some elements are omitted, it may be assumed that the elements with omitted details are at least similar to corresponding elements described elsewhere in the instant disclosure.

FIG. 20 is a plan view illustrating an internal structure of a plasma processing apparatus according to embodiments of the present disclosure.

Referring to FIG. 20, the plasma processing apparatus according to embodiments of the present disclosure may include an RF output rod 670, first to third RF connection lines 671, 672, and 673, and an RF output line 675.

The first RF connection line 671 may have a first portion 671_1 and a second portion 671_2 connected to the first portion 671_1. The second portion 671_2 of the first RF connection line 671 may extend in a direction different from that of the first portion 671_1 of the first RF connection line 671. For example, an inflection point may be formed at the portion where the second portion 671_2 of the first RF connection line 671 and the first portion 671_1 of the first RF connection line 671 are connected.

The third RF connection line 673 may have a first portion 673_1 and a second portion 673_2 connected to the first portion 673_1. The second portion 673_2 of the third RF connection line 673 may extend in a direction different from that of the first portion 673_1 of the third RF connection line 673. For example, an inflection point may be formed at the portion where the second portion 673_2 of the third RF connection line 673 and the first portion 673_1 of the third RF connection line 673 are connected.

One end of the first portion 671_1 of the first RF connection line 671, one end of the second RF connection line 672, one end of the first portion 673_1 of the third RF connection line 673, and one end of the RF output line 675 may be connected to each other.

The angle between the RF output line 675 and the first portion 671_1 of the first RF connection line 671 may be greater than the angle between the RF output line 675 and the second portion 671_2 of the first RF connection line 671. Further, the angle between the RF output line 675 and the first portion 673_1 of the third RF connection line 673 may be greater than the angle between the RF output line 675 and the second portion 673_2 of the third RF connection hue 673.

A fourth angle θ4 between the second RF connection line 672 and the second portion 671_2 of the first RF connection line 671 may be greater than a fifth angle θ5 between the second portion 671_2 of the first RF connection line 671 and the second portion 673_2 of the third RF connection line 673. Further, a sixth angle θ6 between the second RF connection line 672 and the second portion 673_2 of the third RF connection line 673 may be greater than the fifth angle θ5 between the second portion 671_2 of the first RF connection line 671 and the second portion 673_2 of the third RI connection line 673. For example, the fourth angle θ4 between the second RF connection line 672 and the second portion 671_2 of the first RF connection line 671 may be equal to the sixth angle θ6 between the second RF connection line 672 and the second portion 673_2 of the third RF connection line 673.

In the plasma processing apparatus according to embodiments of the present disclosure, the first RF connection line 671 and the third RF connection line 673 disposed at both sides of the RF output line 675 are formed to have an inflection point, so that the RF power transmission paths of the first to third RF connection lines 671, 672, and 673 may be substantially the same. Accordingly, the extent of the etching variation for the wafer W may be reduced.

In concluding the detailed description, those skilled in the art will appreciate that many variations and modifications can be made to the preferred embodiments without substantially departing from the principles of the present disclosure. Therefore, the disclosed embodiments are used in a generic and descriptive sense only and are not necessarily limiting.

What is claimed is:

1. A method for fabricating a semiconductor device, comprising:
providing a wafer on a lower electrode disposed inside a plasma processing apparatus;
providing a first power of a first frequency and a second frequency, lower than the first frequency, to the lower electrode;
inducing a second power, lower than the first power, within a radio frequency (RF) induction electrode using the lower electrode;
releasing a third power, lower than the second power and having the second frequency, to an outside of a chamber; and
performing a plasma process on the wafer while the third power is released to the outside of the chamber,
wherein the RF induction electrode is disposed inside an insulating plate that at least partially surrounds a sidewall of the lower electrode,
wherein the RF induction electrode is spaced apart from the lower electrode, and the RF induction electrode has an annular shape at least partially surrounding the sidewall of the lower electrode, and
wherein the first power is controlled by a first controller, and the third power is controlled by a second controller different from the first controller.

2. The method of claim 1, wherein during the plasma process,
the first controller maintains the first power at a constant first RF power, and
the second controller maintains the third power at a constant second RF power.

3. The method of claim 1, wherein during the plasma process,
the first controller maintains the first power at a constant first RF power, and
the second controller toggles the third power between a second RF power and a third RF power lower than the second RF power at regular intervals.

4. The method of claim 3, wherein the third RF power is 0 Watts.

5. A plasma processing apparatus, comprising:
a chamber in which a plasma process is performed;
a lower electrode disposed inside the chamber and configured to receive a first power of a first frequency and a second frequency lower than the first frequency;
an insulating plate at least partially surrounding a sidewall of the lower electrode;
a focus ring disposed on an edge of the lower electrode and on the insulating plate;
a radio frequency (RF) induction electrode spaced apart from the lower electrode in the insulating plate and having an annular shape at least partially surrounding the sidewall of the lower electrode, a second power lower than the first power being induced within the RF induction electrode using the lower electrode;
an RF output rod connected to the RF induction electrode and configured to release a third power lower than the second power to an outside of the chamber, the third power having the second frequency; and
an RF induction rod connecting the RF induction electrode to the output rod and penetrating the insulating plate.

6. The plasma processing apparatus of claim 5, wherein a distance, in a vertical direction between the RF induction electrode and the focus ring is within a range of 1 mm to 5 mm.

7. The plasma processing apparatus of claim 5, wherein a thickness of the RF induction electrode in it vertical direction is within a range of 5 μm to 100 μm.

8. The plasma processing apparatus of claim 5, wherein a first distance in a horizontal direction between the RF induction electrode and the lower electrode is smaller than a second distance in the horizontal direction between the RF induction rod and the lower electrode.

9. The plasma processing apparatus of claim 5, wherein the RF output rod includes:
a plurality of RF connection lines spaced apart from each other at a same angle, and
an RF output line connected to each of the plurality of RF connection lines and configured to release the third power to the outside of the chamber.

10. The plasma processing apparatus of claim 5, further comprising:
a first controller configured to control the first power; and
a second controller, different from the first controller, configured to control the third power.

11. The plasma processing apparatus of claim 5, further comprising an RF filter connecting the RF induction rod to the RF output rod in the chamber, having a coil shape, and configured to generate the third power by removing the first frequency from the second power.

12. The plasma processing apparatus of claim 11, further comprising a cooling unit at least partially surrounding the RF filter in the chamber and configured to cool the RF filter.

13. The plasma processing apparatus of claim 5, wherein the RF induction rod includes:
a first portion penetrating the insulating plate and having a cylindrical shape; and
a second portion connecting the first portion to the RF output rod.

14. A plasma processing apparatus, comprising:
a chamber in which a plasma process is performed;
a lower electrode disposed inside the chamber and configured to receive a first power of a first frequency and a second frequency lower than the first frequency;
a radio frequency (RF) induction electrode spaced apart from the lower electrode and having an annular shape at least partially surrounding a sidewall of the lower electrode, a second power lower than the first power being induced within the RF induction electrode by the lower electrode;
an RF output rod including a plurality of RF connection lines spaced apart from each other at a same angle and an RF output line connected to each of the plurality of RF connection lines, and configured to release a third power lower than the second power to an outside of the chamber, the third power having the second frequency;
a first controller configured to control the first power; and
a second controller, different from the first controller, configured to control the third power.

15. The plasma processing apparatus of claim 14, further comprising:
an insulating plate at least partially surrounding the sidewall of the lower electrode; and
an RF induction rod connecting the RF induction electrode to the RF output rod and penetrating the insulating plate.

16. The plasma processing apparatus of claim 15, wherein a first distance in a horizontal direction between the RF induction electrode and the lower electrode is smaller than a second distance in the horizontal direction between the RF induction rod and the lower electrode.

17. The plasma processing apparatus of claim 44, further comprising an RF filter connecting the RF induction electrode to the RF output rod in the chamber, having a coil shape, and configured to generate the third power by removing the first frequency from the second power.

18. The plasma processing apparatus of claim 17, further comprising a cooling unit at least partially surrounding the RF filter in the chamber and configured to cool the RF filter.

19. The plasma processing apparatus of claim 14, wherein during the plasma process,
the first controller maintains the first power at a constant first RF power, and
the second controller maintains the third power at a constant second RF power.

20. The plasma processing apparatus of claim 14, wherein during the plasma process,
the first controller maintains the first power at a constant RF power, and
the second controller toggles the third power between a second RF power and a third RF power lower than the second RF power at regular intervals.
